(19) United States
(12) Patent Application Publication
(10) Pub. No.: US 2004/0240684 A1
(43) Pub. Date: Dec. 2, 2004

(54) Automatic and simultaneous control of loudness and loudness compensation of an audio signal

(76) Inventors: Mark Cerasuolo, Redmond, WA (US); Kevin Knoll, Delta (CA)

Correspondence Address: PAUL J. SUTTON, ESQ., BARRY G. MAGIDOFF, ESQ., GREENBERG TRAURIG, LLP, 885 THIRD AVENUE, NEW YORK, NY, 10022, US

(21) Appl. No.: 10/448,500

(22) Filed: May 29, 2003

(51) Int. Cl. H03G 5/00; H03G 3/00

(52) U.S. Cl. 381/104; 381/107; 381/103

(57) ABSTRACT

The invention disclosed is a room volume control that simultaneously and automatically controls both the loudness and the loudness compensation of sound from speakers of an audio system as the volume level is changed. A resistive volume control having a movable contact provides a different resistor value from an input terminal of the volume control to the movable contact for controlling the loudness of an audio signal. A parallel circuit of an inductor and a capacitor coupled through the movable contact is in series with the resistor value of the resistive volume control from the input terminal to the movable contact for controlling the loudness compensation of the audio signal.

### BACKGROUND OF THE INVENTION

1. Field of the Invention

This invention relates generally to equalizing an audio signal and more particularly to automatically and simultaneously controlling the loudness compensation of an audio signal as the loudness of the signal is controlled.

2. Description of the Related Art

Currently audio amplifying systems have a variety of limitations. One limitation is the result of the environment within which the speakers are located and another is the need to control the frequency response of the sound amplifying system as a function of the loudness of the sound.

It has been observed by Fletcher and Munson, while employed at Bell Laboratories, that the frequency response of a human to the level of sound being heard varies with frequency. The Fletcher and Munson contours, generally referred to as equal loudness contours, shows that the human ear has different hearing frequency characteristics which depend on the loudness of the frequency of the signal. Fletcher and Munson determined that at low levels of loudness the human ear is more sensitive to frequencies within the mid range of audible sound, that being between 1 KHz and 4 kHz than to lower and higher frequencies. They also found that at high levels of loudness the frequency sensitivity of the human ear is substantially flat from the low frequency range through the mid and high frequency ranges.

To compensate for this hearing characteristics, tone volume controls (also referred to as equalizers) were developed to boost the low and high frequencies relative to the mid frequency range to compensate for the decreased sensitivity of the ear to the low and high frequencies as the loudness of the signal is decreased.

At the present time both new and existing homes are being wired to accept stereo systems. In an ideal multi room stereo speaker installation, each pair of speakers in each room, will be powered by a separate amplifier that will be controlled from the room with the speakers. However, in practice, it is generally not necessary to have a separate amplifier for each pair of speakers because people in adjacent living areas such as a living room attached to a dining room or a great room having one or more open areas should listen to a common program to prevent each room from generating background noise in adjacent rooms or areas. In addition, in a home that has, for example, 8 speaker zones and two occupants, it is generally unnecessary to have 8 different programs running simultaneously. Also, when an amplifier is connected to power more than one pair of speakers the system becomes more economical.

To use one amplifier for multiple speaker zones, the output of the amplifier must be split Various methods can be used to split the output of an amplifier to feed pairs of speakers in a stereo system. For example, the signal fed to the speakers can be split to connect the speakers in parallel, in series or in a combination of parallel and series. FIG. 1 shows two speakers 10, 12 wired in parallel to amplifier 14. FIG. 2 shows two speakers 16, 18 wired in series to amplifier 20. FIG. 3 shows series connected speakers 22 and 24, and series connected speakers 26 and 28 connected to amplifier 30 to provide a series and parallel speaker wiring arrangement. The preferred method to obtain high quality sound when a signal is split is to connect the speaker in parallel as shown in FIG. 1. With this method the current that flows to one speaker does not go to any other speaker. The current to each speaker flows only to and from the amplifier. The major advantage to parallel speaker wiring is that each speaker will sound its best, even if the two speakers are not similar. The major drawback of parallel wiring is that virtually all amplifiers in use today have a minimum impedance load of between 2 and 8 ohms so that the number of pairs of speakers that can be wired in parallel to an amplifier is usually limited to two pairs. If more than two pairs of speakers are to be connected in parallel to a conventional stereo amplifier or receiver, the speakers must have a high impedance of typically 16 ohms and generally may need a matching transformer and/or some form of current limiting device or a stereo speaker interface.

Series speaker wiring shown in FIG. 2 is an effective method to increase speaker system impedance to a safe operating level for an amplifier. The advantage of series speaker wiring is that many speakers can be used on one amplifier without causing amplifier problems which are associated with low impedance connections. The drawbacks are that dissimilar speakers should not be used in a common series line because neither of the different speaker types will sound its best. This is so because their impedance curves are not identical and each will attempt to draw excessive current at frequencies that the other speaker won't permit. In addition, stereo room volume controls should not be used because when the volume control in one room is turned off, the speakers in the other room will also be turned off.

Referring to FIG. 3, combining series and parallel speaker wiring usually emphasizes the drawbacks of both methods and always lowers the overall reliability of the system. In many cases this method is the only reasonable method possible to connect several speakers to one amplifier. Generally, the sound quality of a system with series and parallel wiring is generally considered superior to using impedance matching transformers including 70 volt line transformers. Only identical speaker models should be wired in the series portions or branch and with a maximum of one volume control or off-on switch for each parallel branch. In this arrangement, the two speakers 22, 24 should be the same model; and the two speakers 26, 28 should be the same model. However, speakers 22 and 24 need not be the same model as speakers 26 and 28.

Speaker level signal splitters are designed to split the signals from the amplifier to multiple pairs of speakers or room volume controls. Ideally, with most multi-room stereo speaker installations and a single amplifier, the speaker output should be controlled from inside the room having the speakers. Control should not be from the room having the amplifier or pre-amplifier. The simplest room speaker control is an on-off switch. A speaker volume control can be used to attenuate speaker level signals to various levels. The ability to turn the speakers fully off is very important in some circumstances, such as when a person wishes to turn off bedroom speakers to sleep.

Autotransformers are popular for both splitting and controlling speaker level signals because they can be inexpensive and effectively control volume levels. Their major drawbacks are that because they are a transformer they cause a non linear phase shift and their amplitude response, which usually drops out at high frequencies and at high signal levels, is not linear at all frequencies. In addition, their dynamic range is limited by the core and winding size. Thus, if a large dynamic range is required, such as for the reproduction of a CD or a laser disc, a bulky expensive core and winding assembly is required. Autotransformers that are reasonably linear with a broadband high dynamic range are generally not practical for common use because of their size and cost.

Where speaker damping factor and high power low frequency applications are not a factor, a resistive V-pad is an excellent volume control. The resistive V-pad volume control has variable input and output impedances with respect to the amplifier and is dependent on both the load impedance connected to the pad and the volume control setting. With a resistive V-pad the phase shift is minimal, the amplitude response (commonly called frequency response) is linear up to and beyond its power rating and heat generation is minimal in the lower and off positions as the V-pad impedance is high in the lower and off positions. Typically, with the volume control knob in the lower and off positions, less than ½ watt, which is not noticeable when touched, is turned into heat.

As noted above, in a central stereo sound system with multiple speaker zones where a zone is assigned to a room, each room should have its own zone volume control. In addition to controlling the volume of the speakers, it is also important that the loudness compensation of the sound for each room should be adjusted as the volume level is changed.

Referring to FIG. 4, there is shown a copy of the Fletcher-Munson curves. At low volumes, the human ear is relatively insensitive especially at low and high frequency extremes.

As the volume increases, human hearing becomes more linear. Loudness compensation of an audio signal is meant to make up for the variances in the sensitivity of human hearing. As noted above, humans tend to be more sensitive to sounds at the middle range of the audio spectrum in terms of pitch (frequency), and less sensitive at either the high or low extremes of the audio spectrum. This is particularly apparent at lower volumes. As the volume of sound increases, the ear tends to be more equally sensitive across the entire audio spectrum than at low volume levels. Thus, at low volumes, a high frequency whistle or a low frequency hum will not be as noticeable as a mid-range tone such as a persons voice.

Loudness compensation is directed toward addressing this variation in sensitivity of the human ear. At low volume levels where there is a relatively large variation in sensitivity of the human ear, the frequencies at the extremes, the low and high frequencies, are amplified and the mid-range frequencies are attenuated or lowered. As the volume level is increased, the magnitude of the loudness compensation is decreased. Thus, extreme frequencies are still amplified, but to a lesser degree and the mid-range frequencies are still attenuated, but at a lesser degree. At high volume levels, the magnitude of the loudness compensation may be little or none since at the high volume, the sensitivity of the human ear is almost uniformly flat. Prior art multi speaker zones single amplifier stereo systems normally have a volume control, and a separate control to compensate for loudness, located adjacent to the stereo amplifier or receiver to control the audio volume of the speakers. The volume control and the loudness controls are not in the same room where the speakers that are being controlled are located, What is needed is a room volume control that automatically controls the loudness compensation of the audio as the volume is changed and can be located within the same room where the speakers that are being controlled are located.

### SUMMARY OF THE INVENTION

The invention disclosed is a room volume control that simultaneously and automatically controls both the loudness and the loudness compensation of sound from speakers of an audio system as the volume level is changed. A resistive volume control having a movable contact provides a different resistor value from an input terminal of the volume control to the movable contact for controlling the loudness of an audio signal. A parallel circuit of an inductor and a capacitor coupled through the movable contact is in series with the resistor value of the resistive volume control from the input terminal to the movable contact for controlling the loudness compensation of the audio signal.

### BRIEF DESCRIPTION OF THE DRAWINGS

Preferred embodiments of the present application are described herein with reference to the drawings in which similar elements are given similar reference characters, wherein:

FIG. 1 shows two speakers connected in parallel to an amplifier;

FIG. 2 shows two speakers connected in series to an amplifier;

FIG. 3 shows two pairs of series connected speakers wired to an amplifier to provide a series and parallel speaker wiring arrangement;

FIG. 4 is a reproduction of the Fletcher-Munson curves;

FIG. 5 shows the frequency response of a resistive volume control; and

FIG. 6 shows an audio loudness control and loudness compensating control in accordance with the principles of the invention.

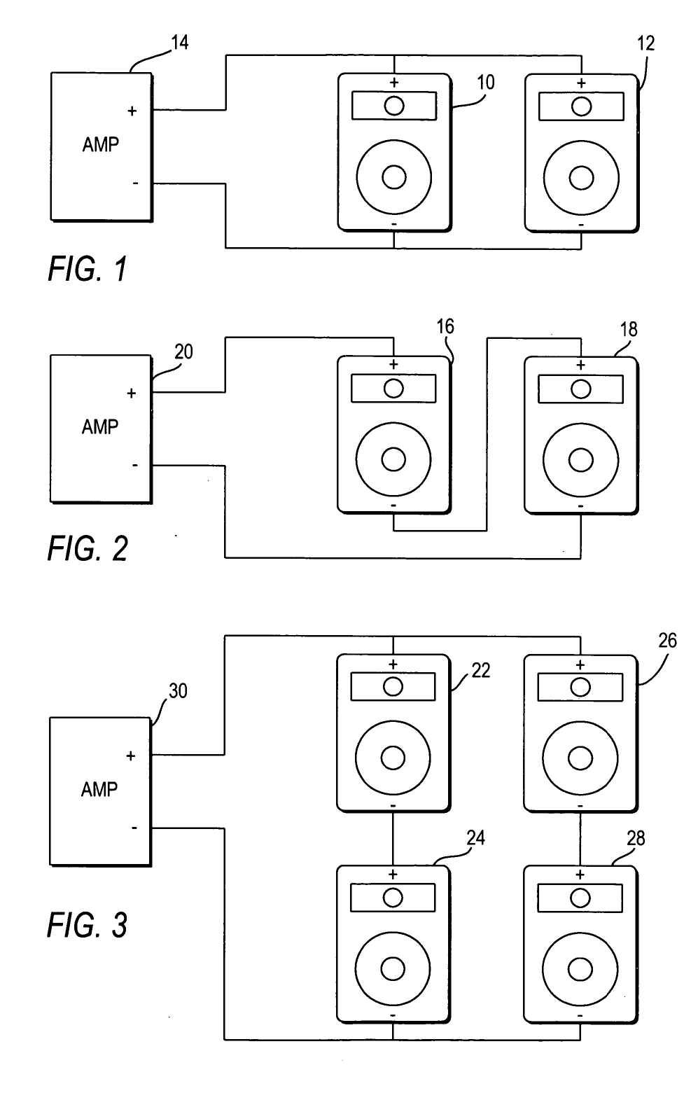

### DETAILED DESCRIPTION

The invention disclosed is a room volume control that simultaneously and automatically controls the loudness compensation of sound from the speakers of a zone of a central audio system having multiple speaker zones as the volume level is changed and where the control can be located in the same room as the speakers that are being controlled.

In an ideal acoustical environment, flat frequency and power response is relatively easy to achieve. But, because of frequency response variables that are inherent in different rooms which are caused by the absorption and/or reflection of sound in a room, the room dimensions, etc., and the way a human hears sounds, audio systems are designed to provide some compensation through base and treble or octave band equalization and loudness control.

Loudness compensation specifically addresses the non-linearity in human hearing by selectively emphasizing the loudness of the signal at very low and high frequency ranges to which the ear is least sensitive, and de-emphasizes mid-range frequencies to which the ear is most sensitive. At the present time loudness compensating circuits are normally based on the Fletcher and Munson curves (FIG. 4) which shows that at low audio volumes the human ear is relatively insensitive to low and high frequencies and, as the audio volume increases, the human ear becomes more linear. Thus, by adjusting low and high frequency controls on an audio amplifier, a listener can hear music with a sense of presence and impact that would normally be missing at lower volume levels where the ear is less sensitive to bass and treble. But, as residential music systems evolved into multi-room systems with multiple speaker pairs and volume controls built into the home, the benefits of tonal and loudness compensation are lost for two reasons. The first is that the listener is often not in the same room as the amplification electronics, the audio amplifier which contains the volume control and the loudness compensation control. The second is that different listeners in different rooms may be listening at different volume levels and, therefore, a loudness compensation control which is set for lower levels of listening may not be adequate for higher levels of audio.

The invention here disclosed is a volume control that simultaneously and automatically controls both the loudness and loudness compensation of audio from the speakers of a zone of a central audio system having multiple speaker zones as the volume level is changed. The control is located in the room where the speakers are located thus enabling a listener to individually adjust the loudness compensation, not just the volume, for each room having installed speakers. The audio control disclosed does this by providing decreasing levels of “boost” at selected frequencies depending on the position of the control, with frequency compensation being most pronounced at lower audio volume levels and reduced at higher volume levels. The effect is less pronounced at higher volume levels which produces a more flat frequency response.

In this invention the volume control has a flat response such as that obtained with the resistive volume control which is linear at all volume levels because it has high quality audio grade resistors. Because the resistive volume control has a flat frequency response, it can be used with passive components to achieve loudness compensation.

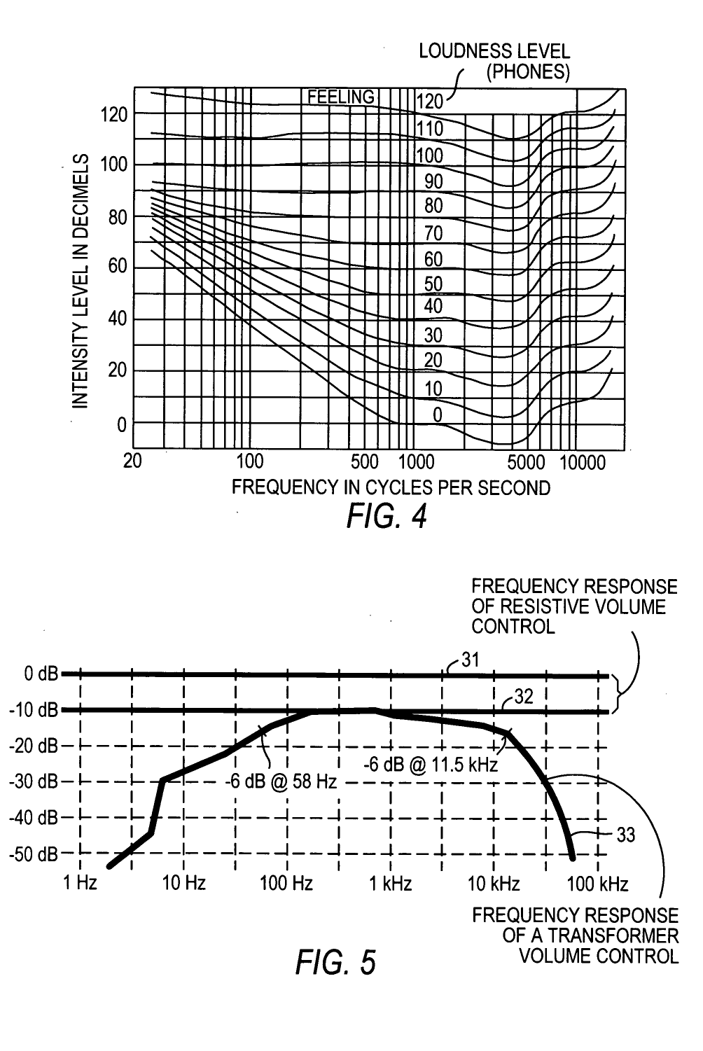

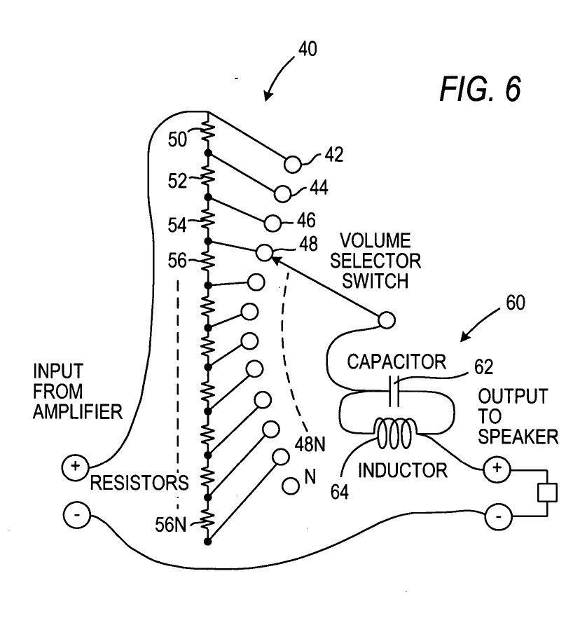

Referring to FIG. 5, straight line curves 31,32 shows the frequency response of a resistive volume control. Because this type of control has inherently flat frequency response, it can be effectively equalized using passive components to achieve loudness compensation in each individual location of a multi room stereo system. For comparison purposes, curve 33 of FIG. 5 shows the frequency response of a transformer volume control. Referring to FIG. 6, there is shown a loudness/loudness compensating control comprised of a resistive volume control connected to a passive circuit in accordance with the principled of the invention. In the resistive volume control 40, each volume control step 42, 44, 46, 48, . . . 48N goes through a resistor 50, 52, 54, 56, . . . 56N to provide the desired level of attenuation. In some versions of resistive volume controls, as shown in FIG. 6, when the highest volume level is selected the amplifier signal passes without attenuation through to the speaker. Coupled to the resistive volume control is one or more passive Band Reject Filters (BFR) 60. The BRFs are connected to receive the attenuated output of the resistive volume control 40, or can be connected between the output stages of the volume control. Normally the filters include a capacitor, inductor and resistor connected in parallel to a high level signal such as the amplifier output or the loudspeaker input positive and negative terminals.

In the control here disclosed, the resistors 50 . . . 56N that are a part of the resistive volume control and are used to provide audio attenuation are also used as components in the BRF circuit 60. As shown in FIG. 6, for the volume control setting illustrated, the BRF circuit to which the audio signal from the amplifier is fed consists of series connected resistors 50, 52 and 54 connected to capacitor 62 in parallel with inductor 64. By selecting an inductor core size for the inductor that saturates when the volume levels are high, and a capacitor 22 that has a complementing value, the loudness compensation effect desired can be realized. With this invention, different frequency contouring effects can be achieved at each level of volume, with bass and treble frequencies emphasized most at the lowest levels and de-emphasized as the audio volume level is increased.

It is to be understood that this invention is not restricted to a volume control having individual resistors connected together and that the volume control can be a carbon member which makes contact with a movable contact to provide a variable resistive value, or the volume control can be a length of resistive wire wrapped around an insulating member along which a movable contact is moved to provide a variable resistive value.

An inherent advantage of this invention is that the BRF circuit can be built into the resistive volume control thus taking advantage of the fact that the resistive volume control includes a series of high quality audio grade resistors. The resistor volume control can consist of resistors positioned into a vertical stack . This is known as a V-pad topology, where the load value, in ohms, as seen by the amplifier increases as the volume selected decreases. To select a particular volume level the volume selector switch is adjusted up or down to a particular contact in the vertical resistor stack.

In operation, as an audio signal exits the resistor volume control 40, the capacitor 62 and inductor 64 add a band reject effect to the signal passing through to shape the signal. As the volume selected goes to a lower level the total resistance of the volume control increases. As this happens the input impedance of the band reject filter increases and thus the amount of band rejection increases to provide more of a loudness effect as the volume selected decreases.

In the higher volume settings when the signal passing through the band reject filter is higher, possibly decades higher, the inductor core becomes increasingly saturated. When this happens the value of the inductance temporarily decreases very rapidly. As the value of the inductance decreases, the amount of band rejection, primarily at the lower frequencies, also decreases. This has the effect of lowering the amount of loudness as the signal level increases.

As different speakers have different characteristics, both the value of the inductance of the inductor and the speed that onset of inductance saturate occurs should be selected to be compatible to the speakers of the audio system to obtain proper loudness compensation with changes in the audio volume. Additional band reject filters can be included between the resistor stages in the volume control to selectively shape the audio signal for desired effects of loudness and other wave shaping requirements.

With this invention, an individual volume control and loudness compensating circuit can be located in each room to control the loudness and loudness compensation of the speakers in that room. It is to be noted that the volume control of this invention is a transformer free volume control that has a plurality of audio grade resistors positioned in close proximity to and connected to band reject filters. Thus, there is disclosed a volume control that simultaneously and automatically controls both the loudness and the loudness compensation of audio from the speakers of a zone of a central audio system having multiple speaker zones as the volume level is changed and where the loudness compensating and volume control is not located back in the electronics but where the speakers are located. In operation, the control increases the amount of loudness compensation by increasing input impedance, and disengages the loudness effect at higher volumes through the inductors own saturation.

The single control for controlling the loudness and loudness compensation of the audio signal here disclosed uses no transformers or active components. It is to be noted that a pair of wide bandwidth 300 watt RMS transformers suitable for quality multi room speaker level splitting have a minimum thickness of 3 to 5 inches and can weigh about 33 lbs. Autotransformer volume controls need to be physically large to have a large dynamic range. Virtually any autotransformer that is large enough to sound acceptable is too big to fit in an electrical junction box. Some transformer volume controls have a depth that is deeper than the depth of a standard house stud which is 3½ inches. Obviously, a transformer type of volume control cannot be easily mounted in a wall of a room. The volume loudness and volume compensation control here disclosed, when designed to operate at 300 watts per channel, is less than 2 inches thick and weighs about 6 pounds. It is so small that electrical junction box backs don't have to be cut out to make then fit.

In another embodiment of this invention, the volume control can be a single resistor having a movable contact that slides along the resistor to provide control of the loudness of an audio signal by changing the value of the resistance of the signal path. This resistance, in series with the parallel circuit of the inductor and capacitor is the Band Reject Filter for controlling the loudness compensation of the signal.

While there have been shown and describer and pointed out the fundamental features of the invention, it will be understood that various omissions and substitutions and changes of the form and details of the device described and illustrated and in its operation may be made by those skilled in the art, without departing from the spirit of the invention.

What is claimed is:

1. An audio loudness and loudness compensation circuit capable of simultaneously and automatically controlling the loudness compensation of audio as the loudness of the audio is changed comprising:
a resistor coupled to an input terminal for receiving an audio signal and a movable contact for moving along the resistor for providing a different resistor value from the input terminal to the movable contact capable of controlling the loudness of audio from a speaker, and
a parallel circuit of a capacitor and an inductor coupled through the movable contact to be in series with the resistor value from the input terminal to the movable contact wherein the resistor value in series with the parallel circuit is a band reject filter capable of controlling the loudness compensation of the audio signal from the speaker.

2. The circuit of claim 1 wherein the resistor is a wire.

3. The circuit of claim 1 wherein the resistor is a wire wound around an insulator.

4. The circuit of claim 1 wherein the resistor is a carbon member.

5. The circuit of claim 1 wherein the inductor has a metal core.

6. The circuit of claim 2 wherein the inductor has a metal core.

7. The circuit of claim 3 wherein the inductor has a metal core.

8. The circuit of claim 4 wherein the inductor has a metal core.

9. An audio loudness and loudness compensation circuit capable of simultaneously and automatically controlling the loudness compensation of audio as the loudness of the audio is changed comprising:
a resistor volume control having at least one input terminal coupled to at least first and second resistors coupled in series and a movable contact adapted to be selectively coupled to the input terminal either directly or through the first or the first and second resistors, and
a capacitor in parallel with an inductor coupled between the movable contact and an output terminal wherein the value of the resistor between the at least one input terminal and the movable contact of the resistor volume control is capable of controlling the loudness of audio from a speaker and the value of the capacitor in parallel with the value of the inductor in combination with the value of the resistor between the at least one input terminal and the movable contact of the resistor volume control is capable of controlling the loudness compensation of audio from the speaker.

10. The circuit of claim 10 wherein the inductor has a metal core.

11. The circuit of claim 9 wherein the capacitor, inductor and series resistor coupled to the capacitor and inductor comprises a passive band reject filter for controlling loudness compensation.

12. The circuit of claim 11 wherein the metal core is magnetic.

13. The circuit of claim 12 wherein, at a selected volume level, the magnetic core of the inductor saturates to cause a decrease of the value of inductance of the inductor.

14. The circuit of claim 13 wherein the decrease of the value of inductance of the inductor is temporary.

15. The circuit of claim 13 wherein the decrease of the value of inductance of the inductor occurs quickly.

16. The circuit of claim 15 wherein the amount of band rejection decreases as the value of the inductance decreases.

17. An audio loudness and loudness compensation control comprising:
a resistive volume control having step contacts located at junctions of series coupled resistors and a movable contact for making contact with a selected one of the step contacts wherein each step contact provides a different resistor value to a signal from an input terminal of the volume control to the movable contact for controlling the loudness of an audio signal, and
a parallel circuit of an inductor and a capacitor coupled in series through the movable contact to a step contact in the resistive volume control for controlling the loudness compensation of the audio signal.

18. The control of claim 17 wherein the inductor of the parallel circuit has a metal core.

19. The control of claim 17 wherein the parallel circuit resonates at a frequency below !000 Hz.

20. The control of claim 17 wherein the parallel circuit and resistors in the resistive volume control from the input terminal to the movable contact form a band reject filter.

21. The control of claim 18 wherein the metal core is magnetic.

22. The control of claim 17 wherein the resistance of the volume control from the input terminal to the movable contact increases as the loudness of audio from the speaker decreases.

23. The control of claim 18 wherein the magnetic core of the inductor is sized to saturate at high loudness levels.

24. The control of claim 23 wherein the magnetic core of the inductor is saturated at a loudness level above 50 Phons.
